(19) United States
(12) Patent Application Publication
(10) Pub. No.: US 2026/0148924 A1
(43) Pub. Date: May 28, 2026

(54) Charged Particle Beam Apparatus and Control Method for Charged Particle Beam Apparatus

(71) Applicant: Hitachi High-Tech Corporation, Minato-ku, Tokyo (JP)

(72) Inventors: Shuhei YABU, Tokyo (JP); Tsunenori NOMAGUCHI, Tokyo (JP); Yu YAMAZAWA, Tokyo (JP); Chisato SAWAHATA, Tokyo (JP); Ryo HIRANO, Tokyo (JP); Naoto ITO, Tokyo (JP)

(21) Appl. No.: 19/122,818

(22) PCT Filed: Nov. 10, 2022
(86) PCT No.: PCT/JP2022/041847

§ 371 Date: Apr. 21, 2025

(51) Int. Cl. H01J 37/14; H01J 37/244; H01J 37/28

(52) U.S. Cl. CPC H01J 37/14; H01J 37/244; H01J 37/28; H01J 2237/21; H01J 2237/24564

(57) ABSTRACT

A reflected electron is detected with high efficiency. The invention includes a charged particle source configured to emit a primary electron beam with which a sample 1 is to be irradiated; a focusing lens configured to focus the primary electron beam; an objective lens 13 configured to form a first magnetic field lens 6 and a second magnetic field lens 7, a first main surface 6a of the first magnetic field lens 6 being disposed on the sample 1 side with respect to a second main surface 7a of the second magnetic field lens 7; a detector 10 disposed on the charged particle source side with respect to the second main surface 7a of the second magnetic field lens 7; and a controller including a processor and a memory. The controller controls a focusing action of the second magnetic field lens 7 to be smaller than a focusing action of the first magnetic field lens 6, causes a signal electron generated from the sample 1 to be focused, and controls an amount of the signal electron reaching the detector 10.

### TECHNICAL FIELD

The present invention relates to a charged particle beam apparatus and a method for controlling a charged particle beam apparatus.

### BACKGROUND ART

In general, a charged particle beam apparatus typified by a scanning electron microscope scans a sample with an electron beam and detects secondary electrons or reflected electrons generated from the sample to obtain a scanning electron microscope image. Observation, inspection, measurement, and the like of a fine object are performed using the scanning electron microscope image.

The performance required for an objective lens of the scanning electron microscope varies depending on a resolution and an intended use of an apparatus. An in-lens objective lens or a semi-in-lens objective lens implements high-resolution observation by leaking a magnetic field to the sample. On the other hand, the out-lens objective lens is inferior in the resolution, but does not leak the magnetic field to the sample, and thus can be used for analysis and observation in a state without the magnetic field and is also suitable for observation at a low magnification.

PTL 1 discloses a scanning electron microscope including both an objective lens for high-magnification observation and an objective lens for low-magnification observation.

PTL 2 discloses an objective lens including a plurality of magnetic poles and a plurality of coils, and having a power supply that supplies current to the plurality of coils independently.

In order to obtain a sample image having high contrast in the scanning electron microscope, it is important to efficiently collect the secondary electrons and the reflected electrons emitted from the sample and selectively collect signal electrons.

PTL 3 discloses a charged particle beam apparatus including a first lens that controls a trajectory of the signal electrons emitted from a sample, and a second lens that changes a focusing condition of a charged particle beam according to a control condition of the first lens.

### CITATION LIST

### Patent Literature

PTL 1: JPH03-230464A

PTL 2: JP2014-41733A

PTL 3: JP2017-16755A

### SUMMARY OF INVENTION

### Technical Problem

Signal electrons generated from a sample are mainly classified into secondary electrons and reflected electrons, each of which has different properties. The secondary electrons are low-energy (50 eV or less) electrons secondarily generated on a surface of the sample, and have a characteristic of easily reflecting a shape of the surface of the sample. On the other hand, the reflected electrons are high-energy electrons obtained by an electron emitted to the sample penetrating the sample, being scattered, and then being emitted outside the sample again, and an image reflecting composition information of the sample can be obtained by the reflected electrons.

In a scanning electron microscope, a detector is provided inside or outside an electron beam column in order to detect these signal electrons. The detector is installed in consideration of a type and a yield of a signal to be acquired. On the other hand, since it is necessary to prevent the signal electrons from interfering with other structures, an installation location of the detector is restricted, which limits the number of detectors that can be installed and detection efficiency of the detector.

In particular, it is generally important to install the detector near the sample in order to detect with high efficiency that reflected electrons having high energy are emitted, except in a region where a magnetic field or a strong electric field of an objective lens is generated, from the sample on a trajectory that diverges linearly.

An object of the invention is to detect reflected electrons with high efficiency.

### Solution to Problem

A charged particle beam apparatus according to the invention including: a charged particle source configured to emit a charged particle beam with which a sample is to be irradiated; a focusing lens configured to focus the charged particle beam; an objective lens configured to form a first lens that is a magnetic field lens or an electrostatic lens and a second lens that is a magnetic field lens or an electrostatic lens, a first main surface of the first lens being disposed on the sample side with respect to a second main surface of the second lens; a detector disposed on the charged particle source side with respect to the second main surface of the second lens; and a controller including a processor and a memory, in which the controller controls a focusing action of the second lens to be smaller than a focusing action of the first lens, causes a signal electron generated from the sample to be focused, and controls an amount of the signal electron reaching the detector.

### Advantageous Effects of Invention

According to the invention, reflected electrons can be detected with high efficiency by a focusing action of a second lens.

Other technical problems and novel features will become apparent from description of the present description and the accompanying drawings.

### BRIEF DESCRIPTION OF DRAWINGS

FIG. 1 is a diagram illustrating an outline of a scanning electron microscope 100 according to Embodiment 1.

FIG. 2 is a hardware block diagram illustrating a control unit 25 according to Embodiment 1.

FIG. 3 is a diagram illustrating details of an objective lens 13 according to Embodiment 1.

FIG. 4 is a diagram illustrating a relation between a distance from a lower surface of the objective lens 13 and an arrival rate of backscattered electrons according to Embodiment 1.

FIG. 5 is a diagram illustrating details of the objective lens 13 and a detector 30 according to Embodiment 2.

FIG. 6 is a diagram illustrating details of the objective lens 13 and a focusing point of a primary electron beam 28 according to Embodiment 3.

FIG. 7 is a diagram illustrating a GUI according to Embodiment 3.

FIG. 8 is a diagram illustrating details of the objective lens 13 and a retarding power supply 34 according to Embodiment 4.

### DESCRIPTION OF EMBODIMENTS

In the following embodiments, when necessary for convenience, the description will be made by being divided into a plurality of sections or embodiments, but unless otherwise stated, they are not unrelated to each other, and one has a relation with all or a part of modifications, details, supplementary explanations, and the like of the other.

In the following embodiments, when referring to the number of elements (including the number, numerical values, amounts, ranges, or the like) or the like, the number of elements is not limited to a specific number, and may be the specific number or more or the specific number or less, unless otherwise specified or except a case where the number is apparently limited to a specific number in principle.

Further, in the following embodiments, it is needless to mention that components (also including element steps and the like) thereof are not necessarily essential unless otherwise specified or unless clearly considered to be essential in principle.

Similarly, in the following embodiments, when a shape, a positional relation, or the like of a component or the like is referred to, the shape or the like is substantially approximate or similar to the shape or the like unless otherwise specified or clearly considered otherwise in principle. The same applies to the above-described numerical values and ranges.

In all drawings for describing the embodiments, the same members are denoted by the same reference numerals in principle, and repeated description thereof will be omitted.

Hereinafter, embodiments of a charged particle beam apparatus according to the invention will be described with reference to the drawings. The charged particle beam apparatus is an apparatus that includes a charged particle beam source that emits a charged particle beam, a lens that focuses the charged particle beam on a sample, and a detector that detects a particle emitted from the sample, and that forms a sample image using a detected signal. Hereinafter, a scanning electron microscope (SEM) will be described as an example of the charged particle beam apparatus.

### Embodiment 1

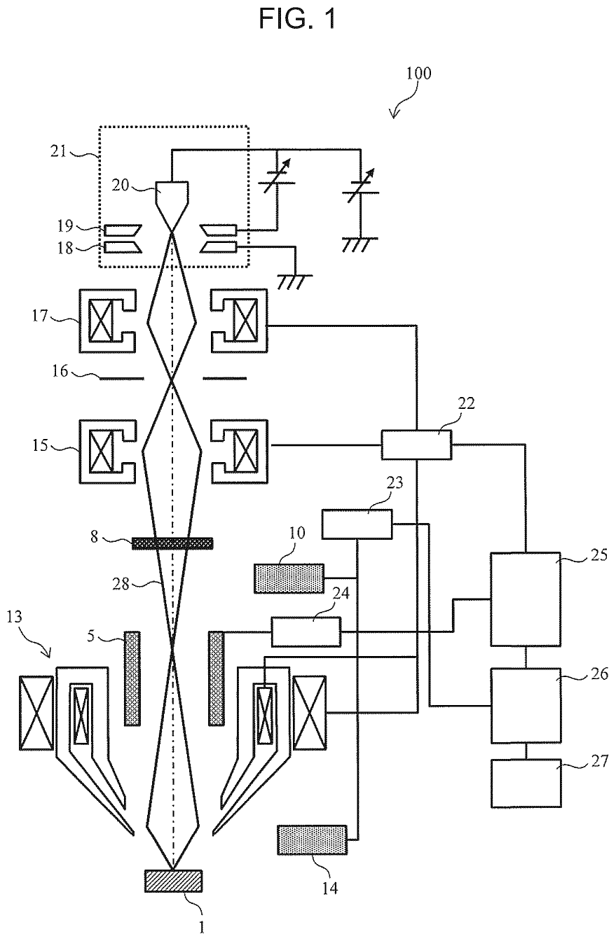

FIG. 1 is a diagram illustrating an outline of a scanning electron microscope (SEM) 100 according to Embodiment 1. In the following description, the SEM will be described as an example, but the charged particle beam apparatus according to the invention is not limited to the SEM, and may be a charged particle beam apparatus other than the SEM in the following embodiments.

An electron gun 21 for emitting an electron beam (primary electron beam 28) includes an electron source 20, an extraction electrode 19 for extracting electrons from the electron source 20, and an acceleration electrode 18 that accelerates the electrons extracted by the extraction electrode 19 toward a sample 1. An acceleration voltage VO is applied to the electron source 20 (charged particle source), and the primary electron beam 28 has acceleration energy V0 due to a potential difference with the acceleration electrode 18 which is at a ground potential. The primary electron beam 28 emitted from the electron gun 21 is focused by a first focusing lens 17, a second focusing lens 15, and an objective lens 13, and is incident on the sample 1. A diaphragm 16 that limits an irradiation amount of the primary electron beam 28 is provided between the first focusing lens 17 and the second focusing lens 15. A focusing condition of each lens is controlled by adjusting an excitation current (applied voltage in the case of an electrostatic lens) supplied from a lens power supply 22.

A deflector 5 is provided to one-dimensionally or two-dimensionally scan the sample 1 with the primary electron beam 28. A signal waveform (line profile) or a two-dimensional image is generated by synchronizing a scanning signal supplied from a scanning signal generator 24 that controls the deflector 5 with an output signal of a detector (detector 10 or detector 14) described later. An excitation current amount of each lens, an amplitude of the scanning signal, and the like are controlled by the control unit 25.

The scanning electron microscope 100 in FIG. 1 is provided with two detectors, the detector 10 and the detector 14. Each of the detector 10 and the detector 14 detects secondary electrons (SE) or backscattered electrons (reflected electrons, BSE) emitted from the sample 1. The detector 14 mainly directly detects the secondary electrons generated from the sample 1. A conversion plate 8 in which a passage opening for the primary electron beam 28 is formed is installed on an optical path of the primary electron beam 28. New secondary electrons (conversion electrons 9, tertiary electrons) generated when the backscattered electrons or the like collide with the conversion plate 8 is detected by the detector 10. Configurations of the detector 10 and the detector 14 are not limited to this combination. A type and an arrangement of the detector, and the number of the detectors may be changed as necessary. A signal output from each of the detector 10 and the detector 14 is amplified by an amplifier 23 and output to an image processing unit 26. The image processing unit 26 converts the amplified signal into the signal waveform or the two-dimensional image, and displays the signal waveform or the two-dimensional image on a display device 27.

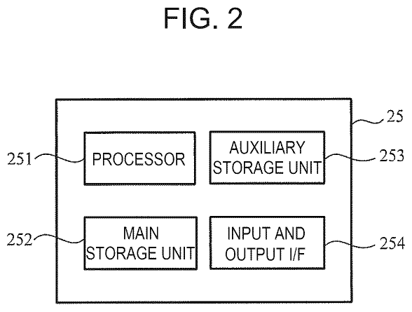

Here, a hardware structure of the control unit 25 according to Embodiment 1 will be described with reference to FIG. 2. FIG. 2 is a hardware block diagram illustrating the control unit 25 according to Embodiment 1. As illustrated in FIG. 2, the control unit 25 (controller) includes a processor 251, a main storage unit (memory) 252, an auxiliary storage unit 253, and an input and output I/F 254. The processor 251 is a central processing unit (CPU), a graphics processing unit (GPU), a digital signal processor (DSP), an application specific integrated circuit (ASIC), or the like. I/F is an abbreviation for interface. The main storage unit 252 is a dynamic random access memory (DRAM) or the like. The auxiliary storage unit 253 is a hard disk drive (HDD), a solid state drive (SSD), or the like, and stores an adjustment program or the like for adjusting a focusing action of each of a first magnetic field lens 6 and a second magnetic field lens 7. The input and output I/F 254 is communicably connected to the lens power supply 22, the scanning signal generator 24, and the image processing unit 26.

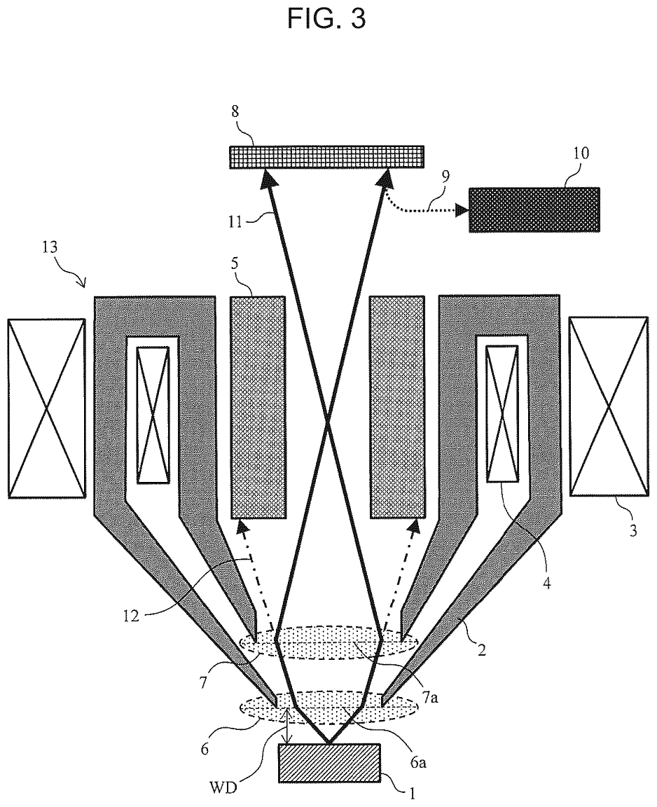

FIG. 3 is a diagram illustrating details of the objective lens 13 according to Embodiment 1. The objective lens 13 includes a magnetic pole 2, a first coil 3, and a second coil 4. A main surface (first main surface) 6a of the first magnetic field lens 6 formed by passing a current through the first coil 3 is formed at a position closer to the sample 1 than a main surface (second main surface) 7a of the second magnetic field lens 7 formed by passing a current through the second coil 4. That is, the second main surface 7a is formed at a position (electron source 20 side) farther from the sample 1 than the first main surface 6a. The objective lens 13 according to Embodiment 1 has a configuration that forms two magnetic field lenses, but may have a configuration that forms a magnetic field lens and an electrostatic lens, or may have a configuration that forms two electrostatic lenses.

In addition, the objective lens 13 may be an out-lens objective lens in which the sample 1 is placed below the objective lens 13, an in-lens objective lens in which the sample 1 is placed inside the objective lens 13, or a semi-in-lens objective lens in which the sample 1 is placed in the middle of the objective lens 13.

In the objective lens 13 that forms two lenses, the lens to be used may be switched depending on a purpose of observation. For example, when it is desired to observe the sample 1 without causing an influence of a magnetic field, it is possible to form only the second magnetic field lens 7 and focus the primary electron beam 28 on the sample 1 by passing the current only through the second coil 4 without passing the current through the first coil 3 (a second mode). On the other hand, when it is desired to observe at a high magnification, it is possible to form only the first magnetic field lens 6 by passing the current only through the first coil 3 without passing the current through the second coil 4 (a first mode). Furthermore, in the present Embodiment 1, in order for the detector 10 to detect the secondary electrons or the backscattered electrons with high efficiency, it is possible to form both the first magnetic field lens 6 and the second magnetic field lens 7 by passing the current through both the first coil 3 and the second coil 4 (a third mode). The control unit 25 switches and uses the first mode, the second mode, and the third mode according to a mode selected by a user depending on the purpose of observation.

Here, a case in which the backscattered electrons are detected using the conversion plate 8 and the detector 10 when observation is performed using only the first magnetic field lens 6 will be considered. The backscattered electrons have high energy equal to or lower than that of the primary electron beam 28, and a portion of the backscattered electrons generated from the sample 1 travel toward the inside of the objective lens 13. The backscattered electrons are subjected to the focusing action of the first magnetic field lens 6 when reaching the first main surface 6a of the first magnetic field lens 6, and therefore, a direction of movement of the backscattered electrons is changed. Since the backscattered electrons that have passed through the first main surface 6a are not subsequently influenced by the magnetic field or an electric field, trajectories 12 of the backscattered electrons diverge. Only a portion of electrons that reach the conversion plate 8 without colliding with a structure inside the objective lens 13, such as the deflector 5, are detected by the detector 10. Instead of the conversion plate 8, a detector that can directly detect the electrons, such as a semiconductor detector, may be installed. The conversion plate 8 is often installed above the objective lens 13, and is at a position away from the sample 1. In addition, it is necessary to install a structure such as the deflector 5 inside the objective lens 13, and it is not possible to increase an inner diameter of a path through which the backscattered electrons pass. Therefore, only a small portion of the backscattered electrons can reach the conversion plate 8.

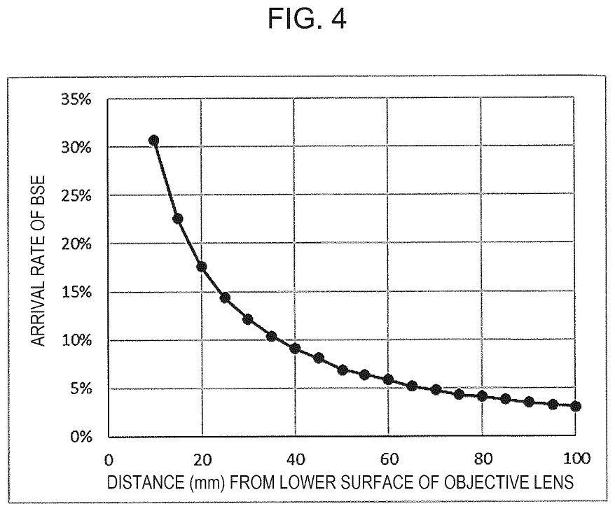

FIG. 4 is a diagram illustrating a result of calculating a proportion of the backscattered electrons that reach the conversion plate 8 among the backscattered electrons generated from the sample 1 when the sample 1 is observed using only the first magnetic field lens 6 formed by the objective lens 13, with respect to each distance from a lower surface of the objective lens 13 to the conversion plate 8, according to Embodiment 1. In this example, the sample 1 is installed at a position where a working distance WD (see FIG. 3) is 4 mm. A size of the conversion plate 8 was calculated to be 10 mm in a diameter. An arrival rate of the backscattered electrons is nearly inversely proportional to the distance from the lower surface (which may be the first main surface 6a) of the objective lens 13 to the conversion plate 8. As a result, when the conversion plate 8 is installed at a position 10 mm away from the lower surface of the objective lens 13, 30% or more of the backscattered electrons emitted from the sample 1 reach the conversion plate 8. On the other hand, when the conversion plate 8 is installed at a position 100 mm away from the lower surface of the objective lens 13, the arrival rate of the backscattered electrons emitted from the sample 1 decreases to 3%.

Therefore, in the present embodiment, a case in which the focusing action of the second magnetic field lens 7 is adjusted so that the backscattered electrons entering the objective lens 13 can reach the conversion plate 8 will be described. As illustrated in FIG. 3, the backscattered electrons that have passed through the first magnetic field lens 6 diverge thereafter. However, by passing the current through the second coil 4 of the objective lens 13 in advance to form the second magnetic field lens 7, trajectories 11 of the diverging backscattered electrons can be focused again. At this time, in Embodiment 1, an amount of the current flowing through the second coil 4 is adjusted such that an amount of the backscattered electrons reaching the conversion plate 8 increases, or an optimum amount of the current is obtained and set in advance by trajectory calculation or the like, whereby detection efficiency for the backscattered electrons can be improved.

When the second magnetic field lens 7 is formed, a lens characteristic is changed as compared with a case in which the primary electron beam 28 is focused on the sample 1 only using the first magnetic field lens 6. In particular, when lens characteristics such as a spherical aberration coefficient and a chromatic aberration coefficient deteriorate, a resolution of an SEM image is influenced, and therefore, it is important to change an intensity of the second magnetic field lens 7 within a range in which there is no influence. Therefore, a range in which the focusing action of the second magnetic field lens 7 on the primary electron beam 28 is used is smaller than a range in which the focusing action of the first magnetic field lens 6 is used. When a focal distance of the second magnetic field lens 7 is larger than a focal distance of the first magnetic field lens 6, it can be said that the focusing action of the second magnetic field lens 7 on the primary electron beam 28 is smaller than the focusing action of the first magnetic field lens 6.

Since more electrons can reach the conversion plate 8 as an arrival rate at which the backscattered electrons reach the second main surface 7a of the second magnetic field lens 7 is larger, a position of the second main surface 7a is an important parameter in designing the apparatus. The arrival rate of the backscattered electrons with respect to the distance from the lower surface of the objective lens 13 to the conversion plate 8 can be checked in FIG. 4.

Assuming that the conversion plate 8 is located at a distance of 100 mm from the lower surface of the objective lens 13, the arrival rate of the backscattered electrons is about 3%. The arrival rate increases as the distance from the lower surface of the objective lens 13 decreases. When the second main surface 7a of the second magnetic field lens 7 is disposed at any position to improve the detection efficiency, the arrival rate at which the backscattered electrons reach the second main surface 7a is important. For example, when the second main surface 7a is disposed at a position 20 mm away from the lower surface (first main surface 6a) of the objective lens 13, the arrival rate at which the backscattered electrons reach the second main surface 7a is about 18%, and it can be expected that the detection efficiency is improved by up to approximately six times at the maximum.

Actually, if the arrival rate can be expected to be approximately three times higher in consideration of a fact that some loss occurs in the number of signals that can reach the detector 10 due to a difference in energy of the backscattered electrons when the backscattered electrons are focused on the second main surface 7a, a significant effect can be obtained in practice. In order to make the arrival rate to be approximately three times higher, it is necessary to dispose the second main surface 7 a at a distance of 40 mm or less from the lower surface (first main surface 6a) of the objective lens.

Here, a method for controlling the scanning electron microscope 100 according to Embodiment 1 will be described. The method for controlling the scanning electron microscope 100 according to Embodiment 1 includes the following processes (1) to (4). An order of the processes may not be the numerical order.

(1) The acceleration voltage VO is applied to the electron gun 21 to emit the primary electron beam 28 from the electron gun 21.

(2) The current is supplied from the lens power supply 22 to the first coil 3 and the second coil 4 to form the first magnetic field lens 6 and the second magnetic field lens 7. The second main surface 7a of the second magnetic field lens 7 is disposed on the electron gun 21 side with respect to the first main surface 6a of the first magnetic field lens 6.

(3) The sample 1 is irradiated with the primary electron beam 28 by the focusing action of the first magnetic field lens 6.

(4) The focusing action of the second magnetic field lens 7 is controlled to be smaller than the focusing action of the first magnetic field lens 6, and signal electrons generated from the sample 1 are focused to reach the detector 10 disposed on the electron gun 21 side with respect to the second main surface 7a of the second magnetic field lens 7.

### Effects of Embodiment 1

In Embodiment 1, by forming the second magnetic field lens 7, it is possible to detect the backscattered electrons (reflected electrons) with high efficiency by the focusing action of the second magnetic field lens 7.

Further, in Embodiment 1, by setting a distance between the first main surface 6a of the first magnetic field lens 6 and the second main surface 7a of the second magnetic field lens 7 to 40 mm or less, it is possible to cause the backscattered electrons to reach the detector 10 at an arrival rate approximately three times higher than that in a case in which the second magnetic field lens 7 is not in operation.

In Embodiment 1, the first magnetic field lens 6 and the second magnetic field lens 7 can be switched and used as in the first mode, the second mode, and the third mode depending on the purpose of observation.

### Embodiment 2

In Embodiment 2, an aspect for improving detection efficiency for backscattered electrons and simultaneously detecting secondary electrons with high efficiency will be described.

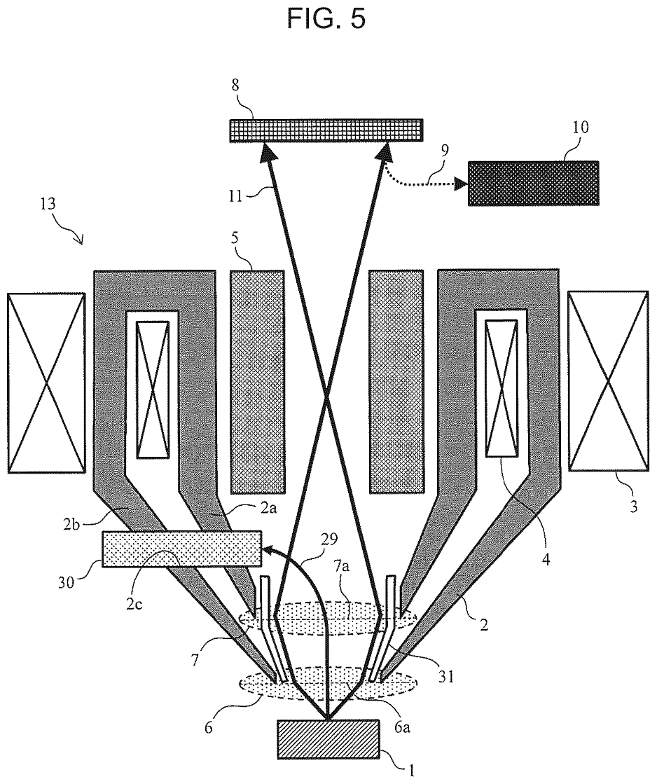

FIG. 5 is a diagram illustrating details of the objective lens 13 according to Embodiment 2. Similarly to Embodiment 1, the objective lens 13 according to Embodiment 2 includes the magnetic pole 2, the first coil 3, and the second coil 4. A detector 30 for detecting secondary electrons 29 is disposed in the objective lens 13.

In addition, in order to improve collection efficiency for the secondary electrons 29, a signal collection electrode 31 is disposed at a tip end of the objective lens 13. The signal collection electrode 31 may be one sheet or a plurality of sheets, and is formed in consideration of the collection efficiency for the secondary electrons 29 and the like. The signal collection electrode 31 may be disposed in the objective lens 13 according to Embodiment 1.

Further, an electrostatic deflector or a magnetic field and electric field orthogonal deflector for bending a trajectory of the secondary electrons 29 toward the detector 30 may be disposed within the objective lens 13.

As described in Embodiment 1, in order to improve the detection efficiency for the backscattered electrons, it is important to bring the position of the second main surface 7a close to the lower surface of the objective lens 13. Although the detector 30 that detects the secondary electrons 29 can be disposed between the first main surface 6a and the second main surface 7a, in order to secure a mounting space for the detector 30, the second main surface 7a has to be disposed at a position away from the lower surface of the objective lens 13.

Therefore, it is effective to install the detector 30 for the secondary electrons 29 on the electron gun 21 side with respect to the second main surface 7a. Therefore, a hole 2c for the detector 30 to pass through is formed in both an inner magnetic path 2a and an outer magnetic path 2b forming the magnetic pole 2 of the objective lens 13, and the detector 30 is installed within the objective lens 13. Accordingly, since a flight distance of the secondary electrons 29 is shortened, trajectory control is facilitated, and the secondary electrons 29 can be detected by the detector 30 without loss.

Further, at this time, if a voltage of the signal collection electrode 31 is set such that an amount of secondary electrons detected according to an operation state of the objective lens 13 is appropriate, loss of the secondary electrons 29 can be minimized.

With such a configuration, as described in Embodiment 1, it is possible to efficiently detect the backscattered electrons by the focusing action of the second magnetic field lens 7 and simultaneously acquire the secondary electrons with high efficiency. Since the backscattered electrons mainly include composition information of the sample 1, and the secondary electrons 29 mainly include shape information of a surface of the sample 1, SEM images having different information can be simultaneously observed.

### Embodiment 3

In Embodiment 3, an aspect for freely selecting the focusing action for signal electrons on the second main surface 7a and improving controllability of the signal electrons will be described. The focusing action on the second main surface 7a influences not only the signal electrons but also the primary electron beam 28. Therefore, when the focusing action on the second main surface 7a is changed, the focusing action on the first main surface 6a also needs to be changed. Further, when the primary electron beam 28 is strongly subjected to the focusing action on the second main surface 7a, a beam diameter of the primary electron beam 28 is also influenced. Therefore, in order to control only a trajectory of the signal electrons with a high degree of freedom, it is desirable that an influence on the primary electron beam 28 is small even when a lens intensity of the second main surface 7a is changed.

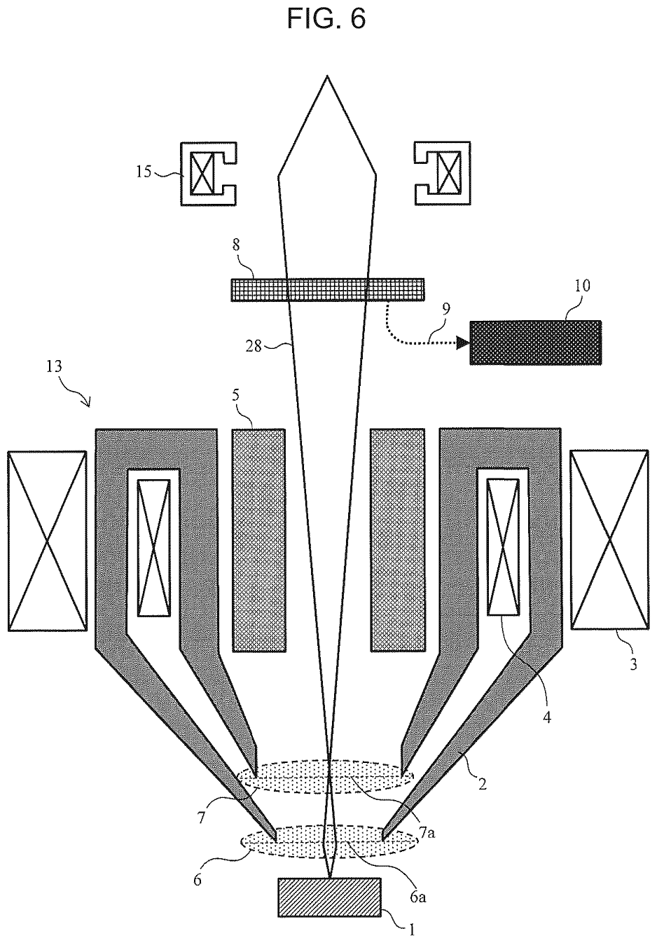

Therefore, in Embodiment 3, as illustrated in FIG. 6, the primary electron beam 28 is focused on the second main surface 7a by using the second focusing lens 15. The control unit 25 controls the second focusing lens 15 such that a position of a focusing point of the primary electron beam 28 with which the sample 1 is to be irradiated coincides with the second main surface 7a. Accordingly, the primary electron beam 28 is hardly subjected to the focusing action on the second main surface 7a, and therefore, the trajectory of the signal electrons can be controlled on the second main surface 7a while maintaining a characteristic of the primary electron beam 28.

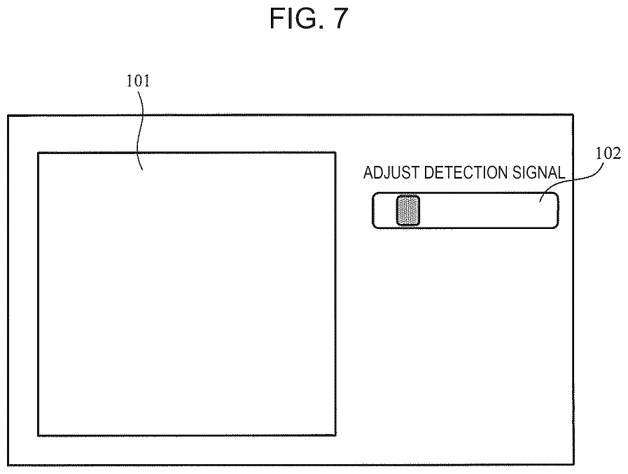

In order for a user to freely control the signal electrons, an adjustment slider 102 (adjustment unit) as illustrated in FIG. 7 may be provided in a user interface (GUI). The focusing action on the second main surface 7a is changed depending on a position (information of the adjustment unit) of the adjustment slider 102 operated by the user, and the user adjusts the adjustment slider 102 to obtain a preferred image while viewing a charged particle beam image displayed on an image display unit 101.

In an example of FIG. 7, the adjustment slider 102 is used to change the focusing action on the second main surface 7a, but a plurality of signal detection modes may be determined in advance by trajectory calculation of a charged particle beam or the like, and the user may select the signal detection mode by a radio button, a selection box, or the like on the GUI.

### Embodiment 4

In Embodiment 4, an aspect for utilizing the invention during an operation of retarding, which is one of observation methods using the scanning electron microscope, will be described.

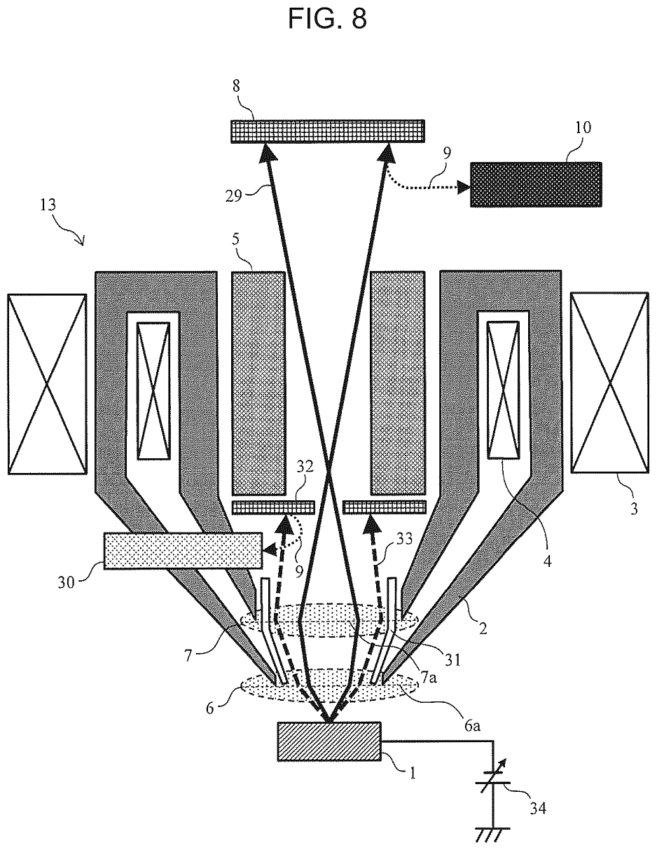

FIG. 8 is a diagram illustrating details of the objective lens 13 according to Embodiment 4. The objective lens 13 according to Embodiment 4 has a same configuration as the objective lens 13 provided with the detector 30 according to Embodiment 2. In addition to a configuration according to Embodiment 2 (see FIG. 5), an apparatus according to Embodiment 4 includes a retarding power supply 34 that applies a retarding voltage to the sample 1, and a conversion plate 32 provided above the detector 30 in the objective lens 13.

The retarding power supply 34 applies the retarding voltage to decelerate the primary electron beam 28 in a vicinity of the sample 1. Accordingly, energy of a primary electron beam with which the sample 1 is to be irradiated is reduced, which is an effective observation method when it is desired to obtain information on the surface of the sample 1 or to reduce damage to the sample 1.

At the time of retarding, signal electrons generated from the sample 1 are accelerated by the retarding voltage and move toward the objective lens 13. The signal electrons pass through the objective lens 13 while being subjected to the focusing action of the objective lens 13 (the first magnetic field lens 6 and the second magnetic field lens 7), but have different trajectories because the energy of the secondary electrons and the energy of the backscattered electrons are different.

In addition, since sample information obtained by the secondary electrons and sample information obtained by the backscattered electrons are different, it is desirable to acquire these pieces of sample information by separate detectors.

In Embodiment 4, by adjusting the focusing action of the second magnetic field lens 7 such that the secondary electrons pass through a center hole of the conversion plate 32, the backscattered electrons can be selectively detected by the detector 30 in the objective lens 13, and the secondary electrons can be selectively detected by the detector 10.

Since the trajectory of the signal electrons also changes depending on the retarding voltage, landing energy of the primary electron beam, and the like, it is desirable to control the focusing action of the second magnetic field lens 7 according to the retarding voltage and the landing energy of the primary electron beam.

In addition, it is also possible to change, by controlling the focusing action of the second magnetic field lens 7, signal information that can be acquired by the detectors 10 and 30. Therefore, the user may freely change the focusing action of the second magnetic field lens 7 to adjust a contrast as desired, or may prepare several conditions having different detection characteristics by calculating the trajectory of the signal electrons in advance, allowing the user to select as needed.

### Modification

The invention is not limited to the above-described embodiments and includes various modifications. For example, the above-described embodiments have been described in detail to facilitate understanding of the invention, and the invention is not necessarily limited to those including all the configurations described above. A part of a configuration of a certain embodiment can be replaced with a configuration of another embodiment, and a configuration of another embodiment can also be added to a configuration of a certain embodiment. In addition, another configuration can be added to a part of a configuration of each embodiment, and the part of the configuration of each embodiment can be deleted or replaced with another configuration.

### Reference Signs List

1: sample
2: magnetic pole
3: first coil
4: second coil
5: deflector
6: first magnetic field lens
6a: first main surface
7: second magnetic field lens
7a: second main surface
8: conversion plate
9: conversion electron
10: detector
11: trajectory (of backscattered electrons focused by second magnetic field lens 7)
12: trajectory (of backscattered electrons at the time when second magnetic field lens is not used)
13: objective lens
14: detector
15: second focusing lens
16: diaphragm
17: first focusing lens
18: acceleration electrode
19: extraction electrode
20: electron source
21: electron gun
22: lens power supply
23: amplifier
24: scanning signal generator
25: control unit
26: image processing unit
27: display device
28: primary electron beam
29: secondary electron
30: detector
31: signal collection electrode
32: conversion plate
33: backscattered electron
34: retarding power supply
101: image display unit
102: adjustment slider

1-17. (canceled)

18. A charged particle beam apparatus comprising:
a charged particle source configured to emit a charged particle beam with which a sample is to be irradiated;
a focusing lens configured to focus the charged particle beam;
an objective lens configured to form a first lens that is a magnetic field lens or an electrostatic lens and a second lens that is a magnetic field lens or an electrostatic lens, a first main surface of the first lens being disposed on the sample side with respect to a second main surface of the second lens;
a detector disposed on the charged particle source side with respect to the second main surface of the second lens; and
a controller including a processor and a memory, wherein
the controller controls a focusing action of the second lens to be smaller than a focusing action of the first lens, causes a signal electron generated from the sample to be focused, and controls an amount of the signal electron reaching the detector.

19. The charged particle beam apparatus according to claim 18, wherein
a distance between the first main surface and the second main surface is 40 mm or less.

20. The charged particle beam apparatus according to claim 18, wherein the controller switches and uses
a first mode in which only the first lens is used,
a second mode in which only the second lens is used, and
a third mode in which the first lens and the second lens are used.

21. The charged particle beam apparatus according to claim 18, further comprising:
another detector disposed on the charged particle source side with respect to the second main surface and on the sample side with respect to the detector.

22. The charged particle beam apparatus according to claim 21, wherein
the objective lens includes a magnetic pole and a coil, and
a hole used for installing the another detector is formed in an inner magnetic path and an outer magnetic path of the magnetic pole.

23. The charged particle beam apparatus according to claim 21, wherein
a signal collection electrode for improving collection efficiency of the detector or the another detector for the signal electron is disposed at a tip end of the objective lens.

24. The charged particle beam apparatus according to claim 18, wherein
the controller controls the focusing lens such that a position of a focusing point of the charged particle beam with which the sample is to be irradiated coincides with the second main surface.

25. The charged particle beam apparatus according to claim 18, further comprising:
a display unit configured to display an adjustment unit for adjusting the focusing action of the second lens, wherein
the controller controls the focusing action of the second lens according to information of the adjustment unit operated by a user.

26. The charged particle beam apparatus according to claim 18, further comprising:
a retarding power supply configured to apply a retarding voltage for decelerating the charged particle beam with which the sample is to be irradiated, wherein
the controller changes the focusing action of the second lens according to energy of the charged particle beam and the retarding voltage.

27. A charged particle beam apparatus comprising:
a charged particle source configured to emit a charged particle beam with which a sample is to be irradiated;
a focusing lens configured to focus the charged particle beam;
an objective lens configured to form a first lens that is a magnetic field lens or an electrostatic lens and a second lens that is a magnetic field lens or an electrostatic lens, a first main surface of the first lens being disposed on the sample side with respect to a second main surface of the second lens;
a first detector disposed on the charged particle source side with respect to the second main surface of the second lens; and
a second detector disposed on the charged particle source side with respect to the second main surface and on the sample side with respect to the first detector, and provided in the objective lens.

28. The charged particle beam apparatus according to claim 27, wherein
a distance between the first main surface and the second main surface is 40 mm or less.

29. The charged particle beam apparatus according to claim 27, wherein
the objective lens includes a magnetic pole and a coil, and
a hole used for installing the second detector is formed in an inner magnetic path and an outer magnetic path of the magnetic pole.

30. The charged particle beam apparatus according to claim 27, wherein
a signal collection electrode for improving collection efficiency of the first detector or the second detector for a signal electron generated from the sample is disposed at a tip end of the objective lens.

31. A method for controlling a charged particle beam apparatus, the charged particle beam apparatus including a charged particle source configured to emit a charged particle beam with which a sample is to be irradiated, a focusing lens configured to focus the charged particle beam, an objective lens configured to form a first lens that is a magnetic field lens or an electrostatic lens and a second lens that is a magnetic field lens or an electrostatic lens, a first main surface of the first lens being disposed on the sample side with respect to a second main surface of the second lens, and a detector disposed on the charged particle source side with respect to the second main surface of the second lens, the method comprising:
emitting the charged particle beam from the charged particle source;
forming the first lens;
forming the second lens such that the second main surface is disposed on the charged particle source side with respect to the first main surface of the first lens;
irradiating the sample with the charged particle beam by a focusing action of the first lens; and
controlling a focusing action of the second lens to be smaller than the focusing action of the first lens, causing a signal electron generated from the sample to be focused, and controlling an amount of the signal electron reaching the detector.

32. The method for controlling a charged particle beam apparatus according to claim 31, further comprising:
focusing the charged particle beam such that a position of a focusing point of the charged particle beam with which the sample is to be irradiated coincides with the second main surface.

33. The method for controlling a charged particle beam apparatus according to claim 31, further comprising:
displaying on a display unit an adjustment unit for adjusting the focusing action of the second lens; and
controlling the focusing action of the second lens according to the adjustment unit operated by a user.

34. The method for controlling a charged particle beam apparatus according to claim 31, further comprising:
changing the focusing action of the second lens according to energy of the charged particle beam and a retarding voltage for decelerating the charged particle beam with which the sample is to be irradiated.
